(19) United States
(12) Patent Application Publication
(10) Pub. No.: US 2022/0076754 A1
(43) Pub. Date: Mar. 10, 2022

(54) MEMORY DEVICE AND METHOD OF OPERATING THE SAME

(71) Applicant: SK hynix Inc., Gyeonggi-do (KR)

(72) Inventor: Gil Bok CHOI, Gyeonggi-do (KR)

(21) Appl. No.: 17/196,215

(22) Filed: Mar. 9, 2021

(30) Foreign Application Priority Data
Sep. 4, 2020 (KR) 10-2020-0113411

(51) Int. Cl. G11C 16/10; G11C 16/04; G11C 16/34; G11C 16/24

(52) U.S. Cl. CPC G11C 16/10; G11C 16/24; G11C 16/3459; G11C 16/0483

(57) ABSTRACT

Provided herein may be a memory device and a method of operating the same. The memory device may include a plurality of memory cells, a peripheral circuit, and a control logic. The peripheral circuit may perform a first program operation and a second program operation on selected memory cells among the plurality of memory cells. The control logic may control the peripheral circuit to apply stepwise increasing and successive program pulses on the selected memory cells in a first program operation, and to apply program pulses and verify pulses on the selected memory cells in the second program operation.

### CROSS-REFERENCE TO RELATED APPLICATION

The present application claims priority under 35 U.S.C. § 119(a) to Korean patent application number 10-2020-0113411, filed on Sep. 4, 2020, in the Korean Intellectual Property Office, the entire disclosure of which is incorporated by reference herein.

### BACKGROUND

### 1. Technical Field

Various embodiments of the present disclosure generally relate to an electronic device, and more particularly to a memory device and a method of operating the memory device.

### 2. Related Art

A storage device stores data under the control of a host device such as a computer or a smartphone. The storage device may include a memory device in which data is stored and a memory controller which controls the memory device. Generally, there are two types of memory devices: volatile memory devices and a nonvolatile memory devices.

In a volatile memory device data is stored only when power is supplied; stored data is lost when the supply of power is interrupted. Exemplary volatile memory devices include a Static Random Access Memory (SRAM) and a Dynamic Random Access Memory (DRAM).

In a nonvolatile memory device stored data is retained even when the supply of power is interrupted. Exemplary nonvolatile memory devices include a Read Only Memory (ROM), a Programmable ROM (PROM), an Electrically Programmable ROM (EPROM), an Electrically Erasable and Programmable ROM (EEPROM), and a flash memory.

### SUMMARY

Various embodiments of the present disclosure are directed to a memory device having improved program operation performance and a method of operating the memory device.

An embodiment of the present disclosure may provide for a memory device. The memory device may include a plurality of memory cells, a peripheral circuit, and a control logic. The peripheral circuit may perform a first program operation and a second program operation on selected memory cells among the plurality of memory cells. The control logic may control the peripheral circuit to apply stepwise increasing and successive program pulses on the selected memory cells in a first program operation, and to apply program pulses and verify pulses on the selected memory cells in the second program operation.

An embodiment of the present disclosure may provide for a method of operating a memory device. The method may include performing a first program operation of applying successive and stepwise increasing program pulses on selected memory cells among a plurality of memory cells; and performing a second program operation on the selected memory cells, the second program operation including a program verify operation and a program pulse apply operation.

An embodiment of the present disclosure may provide for a memory device. The memory device may include a plurality of memory cells, a peripheral circuit, and control logic. The peripheral circuit may apply one or more voltages to a word line coupled to selected memory cells among the plurality of memory cells. The one or more voltages are associated with one or more program operations on the selected memory cells. The control logic may control the peripheral circuit to perform a coarse program operation and a fine program operation on the selected memory cells, the coarse program operation including a program operation of applying ramp pulses and excluding a program verify operation and the fine program operation including a program operation and a program verify operation.

### BRIEF DESCRIPTION OF THE DRAWINGS

FIG. 1 is a diagram illustrating a storage device according to an embodiment of the present disclosure.

FIG. 2 is a diagram illustrating the structure of a memory device of FIG. 1.

FIG. 3 is a diagram illustrating a memory cell array of FIG. 2.

FIG. 4 is a diagram illustrating an embodiment of the memory cell array of FIG. 2.

FIG. 5 is a circuit diagram illustrating any one memory block BLKa of memory blocks BLK1 to BLKz of FIG. 4.

FIG. 6 is a circuit diagram illustrating an example of any one memory block BLKb of the memory blocks BLK1 to BLKz of FIG. 4.

FIG. 7 is a diagram illustrating a configuration of a program setting table storage of FIG. 2.

FIG. 8 is a diagram illustrating a coarse program operation (Coarse PGM) and a fine program operation (Fine PGM) according to an embodiment.

FIG. 9 is a diagram illustrating a ramp pulse program operation.

FIG. 10 is a diagram illustrating an incremental step pulse program (ISPP) operation.

FIG. 11 is a flowchart illustrating operation of a memory device according to an embodiment.

### DETAILED DESCRIPTION

Specific structural and functional description is provided to describe embodiments of the present disclosure. The invention, however, may be practiced in various forms and ways, and thus should not be construed as being limited to the embodiments described herein. Throughout the specification, reference to “an embodiment” or the like is not necessarily to only one embodiment, and different references to any such phrase are not necessarily to the same embodiment(s). The term “embodiments” when used herein does not necessarily refer to all embodiments.

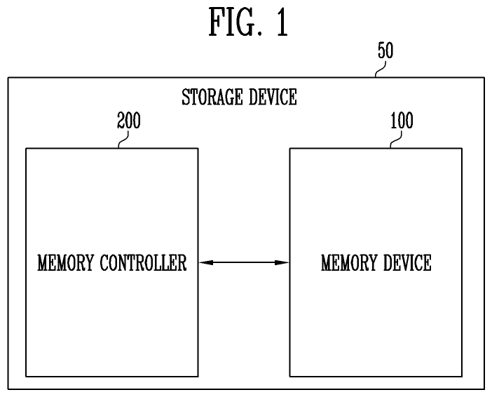

FIG. 1 is a diagram illustrating a storage device 50 according to an embodiment of the present disclosure.

Referring to FIG. 1, the storage device 50 may include a memory device 100 and a memory controller 200 which controls the operation of the memory device 100. The storage device 50 may store data under the control of a host (not shown), such as a mobile phone, a smartphone, an MP3 player, a laptop computer, a desktop computer, a game console, a television (TV), a tablet PC, or an in-vehicle infotainment system.

The storage device 50 may be manufactured or configured as any of various types of storage devices depending on a host interface that is a scheme for communication with the host. The storage device 50 may be implemented as, for example, a solid state drive (SSD), a multimedia card such as an MMC, an embedded MMC (eMMC), a reduced size MMC (RS-MMC), or a micro-MMC, a secure digital card such as an SD, a mini-SD, or a micro-SD, a universal serial bus (USB) storage device, a universal flash storage (UFS) device, a personal computer memory card international association (PCMCIA) card-type storage device, a peripheral component interconnection (PCI)-card type storage device, a PCI express (PCI-e or PCIe) card-type storage device, a compact flash (CF) card, a smart media card, and/or a memory stick.

The storage device 50 may be manufactured in any of various types of packages. For example, the storage device 50 may be manufactured as package on package (POP), system in package (SIP), system on chip (SOC), multi-chip package (MCP), chip on board (COB), wafer-level fabricated package (WFP), and/or wafer-level stack package (WSP).

The memory device 100 may store data. The memory device 100 is operated in response to the control of the memory controller 200. The memory device 100 may include a memory cell array including a plurality of memory cells which store data.

Each of the memory cells may be implemented as a single-level cell (SLC) capable of storing single bit of data, a multi-level cell (MLC) capable of storing two bits of data, a triple-level cell (TLC) capable of storing three bits of data, or a quad-level cell (QLC) capable of storing four bits of data.

The memory cell array may include a plurality of memory blocks. Each memory block may include a plurality of memory cells. A single memory block may include a plurality of pages. In an embodiment, each page may be a unit by which data is stored in the memory device 100 or by which data stored in the memory device 100 is read.

A memory block may be a unit by which data is erased. In an embodiment, the memory device 100 may take many alternative forms, such as a double data rate synchronous dynamic random access memory (DDR SDRAM), a low power double data rate fourth generation (LPDDR4) SDRAM, a graphics double data rate (GDDR) SDRAM, a low power DDR (LPDDR) SDRAM, a Rambus dynamic random access memory (RDRAM), a NAND flash memory, a vertical NAND flash memory, a NOR flash memory device, a resistive RAM (RRAM), a phase-change random access memory (PRAM), a magnetoresistive RAM (MRAM), a ferroelectric RAM (FRAM), or a spin transfer torque RAM (STT-RAM). By way of example, features and aspects of the present invention are described in the context in which the memory device 100 is a NAND flash memory.

The memory device 100 may receive a command and an address from the memory controller 200, and may access the area of the memory cell array, selected by the address. That is, the memory device 100 may perform an operation indicated by the command on the area selected by the address. For example, the memory device 100 may perform a write operation (i.e., program operation), a read operation, and an erase operation. During a program operation, the memory device 100 may program data to the area selected by the address. During a read operation, the memory device 100 may read data from the area selected by the address. During an erase operation, the memory device 100 may erase data stored in the area selected by the address.

The memory controller 200 controls overall operation of the storage device 50.

When power is applied to the storage device 50, the memory controller 200 may run firmware (FW). When the memory device 100 is a flash memory device, the memory controller 200 may run firmware such as a flash translation layer (FTL) for controlling communication between the host and the memory device 100.

In an embodiment, the memory controller 200 may receive data and a logical block address (LBA) from the host, and may translate the logical block address (LBA) into a physical block address (PBA) indicating the address of memory cells which are included in the memory device 100 and in which data is to be stored.

The memory controller 200 may control the memory device 100 so that a program operation, a read operation or an erase operation is performed in response to a request received from the host. During a program operation, the memory controller 200 may provide a write command, a physical block address (PBA), and data to the memory device 100. During a read operation, the memory controller 200 may provide a read command and a physical block address (PBA) to the memory device 100. During an erase operation, the memory controller 200 may provide an erase command and a physical block address (PBA) to the memory device 100.

In an embodiment, the memory controller 200 may autonomously generate a command, an address, and data regardless of whether a request from the host is received, and may transmit them to the memory device 100. For example, the memory controller 200 may provide commands, addresses, and data to the memory device 100 so as to perform background operations, such as a program operation for wear leveling and a program operation for garbage collection.

In an embodiment, the memory controller 200 may control at least two memory devices 100. In this case, the memory controller 200 may control the memory devices 100 using an interleaving scheme to improve operating performance. The interleaving scheme may be an operating manner in which the operating periods of at least two memory devices 100 are caused to overlap each other.

The host may communicate with the storage device 50 using at least one of various communication methods such as Universal Serial Bus (USB), Serial AT Attachment (SATA), Serial Attached SCSI (SAS), High Speed Interchip (HSIC), Small Computer System Interface (SCSI), Peripheral Component Interconnection (PCI), PCI express (PCIe), Nonvolatile Memory express (NVMe), Universal Flash Storage (UFS), Secure Digital (SD), MultiMedia Card (MMC), embedded MMC (eMMC), Dual In-line Memory Module (DIMM), Registered DIMM (RDIMM), and Load Reduced DIMM (LRDIMM) communication methods.

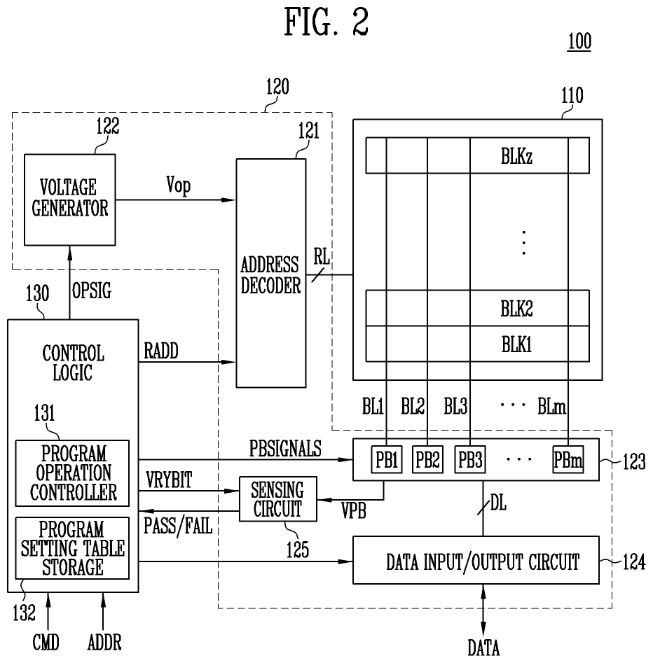

FIG. 2 is a diagram illustrating the structure of the memory device 100 of FIG. 1.

Referring to FIG. 2, the memory device 100 may include a memory cell array 110, a peripheral circuit 120, and control logic 130.

The memory cell array 110 includes a plurality of memory blocks BLK1 to BLKz. The plurality of memory blocks BLK1 to BLKz are coupled to an address decoder 121 through row lines RL. The memory blocks BLK1 to BLKz are coupled to a read and write circuit 123 through bit lines BL1 to BLm. Each of the memory blocks BLK1 to BLKz includes a plurality of memory cells. In an embodiment, the plurality of memory cells are nonvolatile memory cells. In the plurality of memory cells, memory cells coupled to the same word line are defined as a single physical page. That is, the memory cell array 110 is composed of a plurality of physical pages. In accordance with an embodiment of the present disclosure, each of the plurality of memory blocks BLK1 to BLKz in the memory cell array 110 may include a plurality of dummy cells. As the dummy cells, one or more dummy cells may be coupled in series between a drain select transistor and the memory cells and between a source select transistor and the memory cells.

Each of the memory cells of the memory device 100 may be implemented as a single-level cell (SLC) capable of storing single bit of data, a multi-level cell (MLC) capable of storing two bits of data, a triple-level cell (TLC) capable of storing three bits of data, or a quad-level cell (QLC) capable of storing four bits of data.

The peripheral circuit 120 may include the address decoder 121, a voltage generator 122, the read and write circuit 123, a data input/output circuit 124, and a sensing circuit 125.

The peripheral circuit 120 may drive the memory cell array 110. For example, the peripheral circuit 120 may drive the memory cell array 110 so that a program operation, a read operation, and an erase operation are performed.

The address decoder 121 is coupled to the memory cell array 110 through row lines RL. The row lines RL may include drain select lines, word lines, source select lines, and a common source line. In accordance with an embodiment of the present disclosure, the word lines may include normal word lines and dummy word lines. In accordance with an embodiment of the present disclosure, the row lines RL may further include a pipe select line.

The address decoder 121 may be operated under the control of the control logic 130. The address decoder 121 receives addresses ADDR from the control logic 130.

The address decoder 121 may decode a block address, among the received addresses ADDR. The address decoder 121 selects at least one of the memory blocks BLK1 to BLKz according to the decoded block address. The address decoder 121 may decode a row address among the received addresses ADDR. The address decoder 121 may select at least one of word lines of the selected memory block according to the decoded row address. The address decoder 121 may apply operating voltages Vop supplied from the voltage generator 122 to the selected word line.

During a program operation, the address decoder 121 may apply a program voltage to the selected word line and apply a pass voltage having a level lower than that of the program voltage to unselected word lines. During a program verify operation, the address decoder 121 may apply a verify voltage to a selected word line and apply a verify pass voltage having a level higher than that of the verify voltage to unselected word lines.

During a read operation, the address decoder 121 may apply a read voltage to a selected word line and apply a read pass voltage having a level higher than that of the read voltage to unselected word lines.

In accordance with an embodiment of the present disclosure, the erase operation of the memory device 100 may be performed on a memory block basis. During an erase operation, the addresses ADDR input to the memory device 100 include a block address. The address decoder 121 may decode the block address and select a single memory block in response to the decoded block address. During the erase operation, the address decoder 121 may apply a ground voltage to word lines coupled to the selected memory block.

In accordance with an embodiment of the present disclosure, the address decoder 121 may decode a column address among the received addresses ADDR. The decoded column address may be transferred to the read and write circuit 123. In an embodiment, the address decoder 121 may include components such as a row decoder, a column decoder, and an address buffer.

The voltage generator 122 may generate a plurality of operating voltages Vop using an external supply voltage that is supplied to the memory device 100. The voltage generator 122 may be operated under the control of the control logic 130.

In an embodiment, the voltage generator 122 may generate an internal supply voltage by regulating the external supply voltage. The internal supply voltage generated by the voltage generator 122 is used as an operating voltage for the memory device 100.

In an embodiment, the voltage generator 122 may generate the plurality of operating voltages Vop using the external supply voltage or the internal supply voltage. The voltage generator 122 may generate various voltages for use by the memory device 100. For example, the voltage generator 122 may generate a plurality of erase voltages, a plurality of program voltages, a plurality of pass voltages, a plurality of select read voltages, and a plurality of unselect read voltages.

The voltage generator 122 may include a plurality of pumping capacitors for receiving the internal supply voltage so as to generate a plurality of operating voltages Vop having various voltage levels. The voltage generator 122 may generate the plurality of operating voltages Vop by selectively enabling the plurality of pumping capacitors under the control of the control logic 130.

The generated operating voltages Vop may be supplied to the memory cell array 110 by the address decoder 121.

The read and write circuit 123 includes first to m-th page buffers PB1 to PBm, which are coupled to the memory cell array 110 through the first to m-th bit lines BL1 to BLm, respectively. The first to m-th page buffers PB1 to PBm are operated under the control of the control logic 130.

The first to m-th page buffers PB1 to PBm perform data communication with the data input/output circuit 124. During a program operation, the first to m-th page buffers PB1 to PBm receive data DATA to be stored through the data input/output circuit 124 and data lines DL.

During a program operation, the first to m-th page buffers PB1 to PBm may transfer the data DATA to be stored, received through the data input/output circuit 124, to selected memory cells through the bit lines BL1 to BLm when a program pulse is applied to a selected word line. Memory cells in a selected page are programmed based on the received data DATA. Memory cells coupled to a bit line to which a program permission (enable) voltage (e.g., a ground voltage) is applied may have increased threshold voltages. The threshold voltages of memory cells coupled to a bit line to which a program inhibit voltage (e.g., a supply voltage) is applied may be maintained. During a program verify operation, the first to m-th page buffers PB1 to PBm read the data DATA stored in the selected memory cells from the selected memory cells through the bit lines BL1 to BLm.

During a read operation, the read and write circuit 123 may read data DATA from the memory cells in the selected page through the bit lines BL, and may store the read data DATA in the first to m-th page buffers PB1 to PBm.

During an erase operation, the read and write circuit 123 may allow the bit lines BL to float. In an embodiment, the read and write circuit 123 may include a column select circuit.

The data input/output circuit 124 is coupled to the first to m-th page buffers PB1 to PBm through the data lines DL. The data input/output circuit 124 is operated in response to the control of the control logic 130.

The data input/output circuit 124 may include a plurality of input/output buffers (not illustrated) which receive input data DATA. During a program operation, the data input/output circuit 124 receives the data DATA to be stored from an external controller (not illustrated). During a read operation, the data input/output circuit 124 outputs the data DATA, received from the first to m-th page buffers PB1 to PBm included in the read and write circuit 123, to the external controller.

During a read operation or a verify operation, the sensing circuit 125 may generate a reference current in response to an enable bit signal VRYBIT generated by the control logic 130. Further, the sensing circuit 125 may output a pass signal or a fail signal to the control logic 130 by comparing a sensing voltage VPB received from the read and write circuit 123 with a reference voltage generated by the reference current.

The control logic 130 may be coupled to the address decoder 121, the voltage generator 122, the read and write circuit 123, the data input/output circuit 124, and the sensing circuit 125. The control logic 130 may control overall operation of the memory device 100. The control logic 130 may be operated in response to a command CMD transmitted from an external device.

The control logic 130 may control the peripheral circuit 120 by generating various types of signals in response to the command CMD and the addresses ADDR. For example, the control logic 130 may generate an operation signal OPSIG, an address ADDR, read and write circuit control signals PBSIGNALS, and an enable bit VRYBIT in response to the command CMD and the addresses ADDR. The control logic 130 may output the operation signal OPSIG to the voltage generator 122, output the address ADDR to the address decoder 121, output the read and write circuit control signals PBSIGNALS to the read and write circuit 123, and output the enable bit VRYBIT to the sensing circuit 125. In addition, the control logic 130 may determine whether a verify operation has passed or failed in response to the pass or fail signal PASS or FAIL output from the sensing circuit 125.

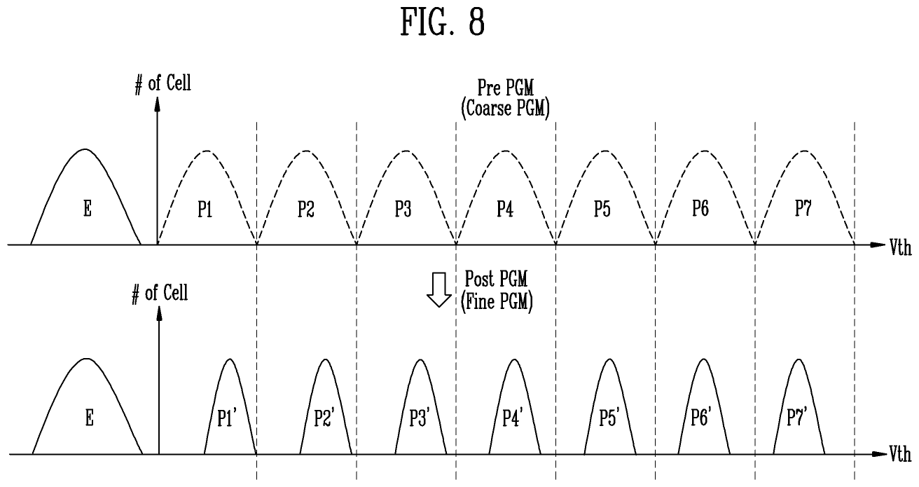

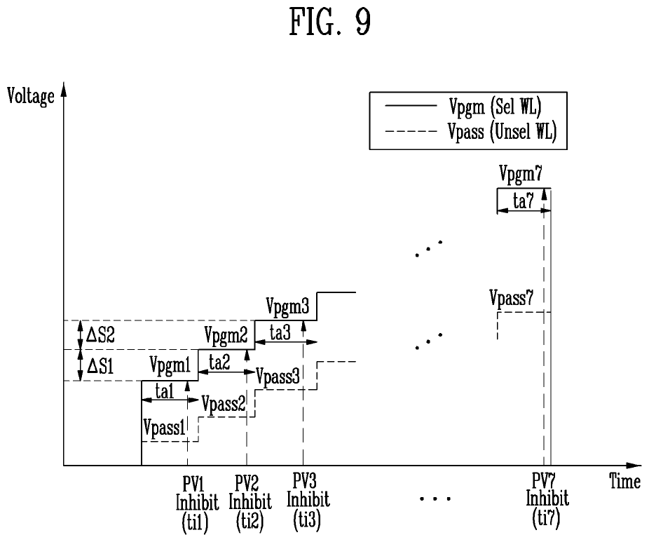

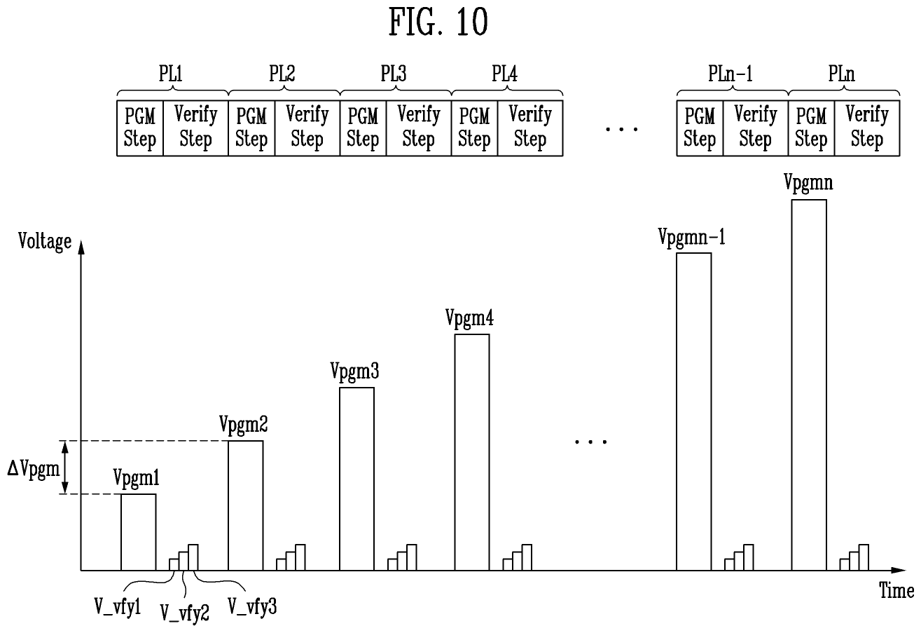

In an embodiment, the control logic 130 may control the peripheral circuit 120 so that a first program operation and a second program operation are performed on memory cells selected from among the plurality of memory cells. In an embodiment, the first program operation may be a coarse program operation, and the second program operation may be a fine program operation, as is described below with reference to FIG. 8. In an embodiment, the first program operation may be a ramp pulse program operation, which is described below with reference to FIG. 9. The second program operation may be an incremental step pulse program (ISPP)_operation, which is described below with reference to FIG. 10.

For example, the control logic 130 may control the peripheral circuit 120 so that a program pulse increased step by step is successively applied without performing a program verify operation during the first program operation. The control logic 130 may control the peripheral circuit 120 so that a plurality of program loops, each including a program verify operation and a program pulse apply operation, are performed during the second program operation.

The control logic 130 may include a program operation controller 131 and a program setting table storage 132.

The program operation controller 131 may control the peripheral circuit 120 so that the first program operation and the second program operation are performed on memory cells selected from among the plurality of memory cells.

The program setting table storage 132 may store program setting values related to the first program operation and the second program operation.

In an embodiment, the program setting values related to the first program operation may include information about a program voltage level, information about a program voltage applying time, and information about a program inhibit time point which individually correspond to a target program state of the selected memory cells in the first program operation.

In an embodiment, the program setting values related to the second program operation may include information about a program voltage level and information about a program voltage applying time which individually correspond to a target program state of the selected memory cells in the second program operation. In the second program operation, the program inhibit time point may be determined based on the result of a program verify operation.

The program operation controller 131 may control the peripheral circuit 120 so that a program voltage corresponding to the target program state of the selected memory cells, which is determined based on the program voltage level information, is applied to a selected word line coupled to the selected memory cells during the first program operation. Here, the program operation controller 131 may control the peripheral circuit 120 so that the determined program voltage is applied to the selected word line during the program voltage applying time corresponding to the target program state, which is determined based on the program voltage applying time information. In an embodiment, the program operation controller 131 may control the peripheral circuit 120 so that a program voltage increased step by step is successively applied to the selected word line as the target program state becomes higher.

In an embodiment, the program voltage may be increased by a constant increment when the target program state becomes higher. In various embodiments, the program voltage may be increased by an increment determined for the target program state when the corresponding target program state becomes higher.

The program operation controller 131 may control the peripheral circuit 120 so that a program inhibit voltage is applied to bit lines coupled to the selected memory cells at a program inhibit time point corresponding to the target program state of the selected memory cells, based on the program inhibit time point information during the first program operation.

The program operation controller 131 may control the peripheral circuit 120 so that a program pass voltage is applied to unselected word lines coupled to unselected memory cells, among the plurality of memory cells. The program operation controller 131 may control the peripheral circuit 120 so that a program pass voltage increased step by step is successively applied to the unselected word lines as the target program state becomes higher.

In other embodiments, the program operation controller 131 may control the peripheral circuit 120 so that a program pass voltage having the same level is successively applied to the unselected word lines.

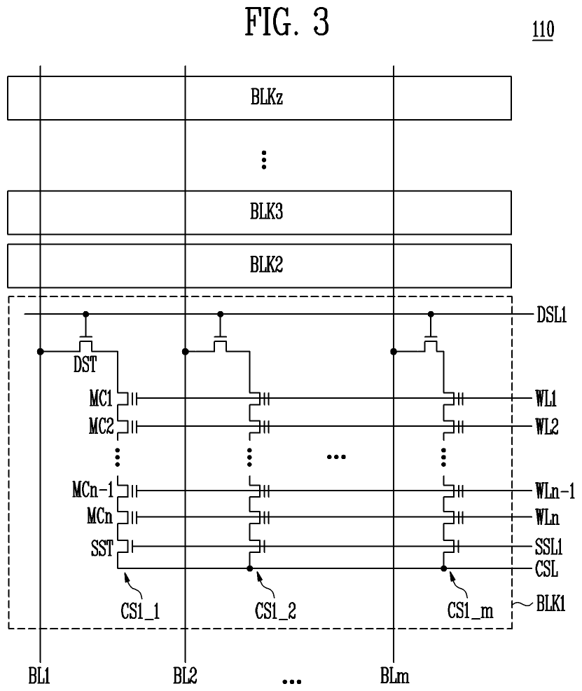

FIG. 3 is a diagram illustrating the memory cell array 110 of FIG. 2.

Referring to FIG. 3, the first to z-th memory blocks BLK1 to BLKz are coupled in common to the first to m-th bit lines BL1 to BLm. In FIG. 3, by way of example, elements in the first memory block BLK1, among the plurality of memory blocks BLK1 to BLKz, are illustrated. Each of the remaining memory blocks BLK2 to BLKz has the same configuration as the first memory block BLK1.

The memory block BLK1 may include a plurality of cell strings CS1_1 to CS1_m (where m is a positive integer). The first to m-th cell strings CS1_1 to CS1_m are respectively coupled to the first to m-th bit lines BL1 to BLm. Each of the first to m-th cell strings CS1_1 to CS1_m may include a drain select transistor DST, a plurality of memory cells MC1 to MCn (where n is a positive integer) which are coupled in series to each other, and a source select transistor SST.

A gate terminal of the drain select transistor DST in each of the first to m-th cell strings CS1_1 to CS1_m is coupled to a drain select line DSL1. Gate terminals of the first to n-th memory cells MC1 to MCn in each of the first to m-th cell strings CS1_1 to CS1_m are coupled to first to n-th word lines WL1 to WLn, respectively. A gate terminal of the source select transistor SST in each of the first to m-th cell strings CS1_1 to CS1_m is coupled to a source select line SSL1.

By way of example, the structure of each cell string is described based on the first cell string CS1_1, among the plurality of cell strings CS1_1 to CS1_m. Each of the remaining cell strings CS1_2 to CS1_m is configured in the same manner as the first cell string CS1_1.

A drain terminal of the drain select transistor DST in the first cell string CS1_1 is coupled to the first bit line BL1. A source terminal of the drain select transistor DST in the first cell string CS1_1 is coupled to a drain terminal of the first memory cell MC1 in the first cell string CS1_1. The first to n-th memory cells MC1 to MCn may be coupled in series to each other. A drain terminal of the source select transistor SST in the first cell string CS1_1 is coupled to a source terminal of the n-th memory cell MCn in the first cell string CS1_1. A source terminal of the source select transistor SST in the first cell string CS1_1 is coupled to a common source line CSL. In an embodiment, the common source line CSL may be coupled in common to the first to z-th memory blocks BLK1 to BLKz.

The drain select line DSL1, the first to n-th word lines WL1 to WLn, and the source select line SSL1 are included in the row lines RL of FIG. 2. The drain select line DSL1, the first to n-th word lines WL1 to WLn, and the source select line SSL1 are controlled by the address decoder 121. The common source line CSL is controlled by the control logic 130. The first to m-th bit lines BL1 to BLm are controlled by the read and write circuit 123.

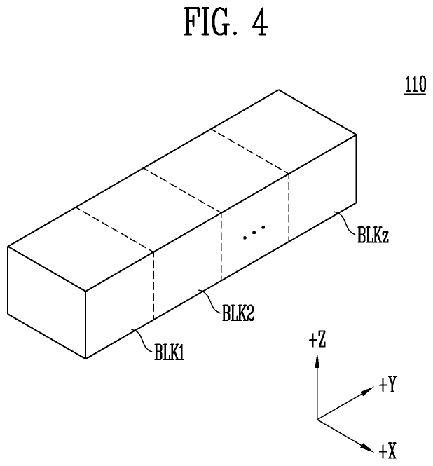

FIG. 4 is a diagram illustrating an embodiment of the memory cell array 110 of FIG. 2.

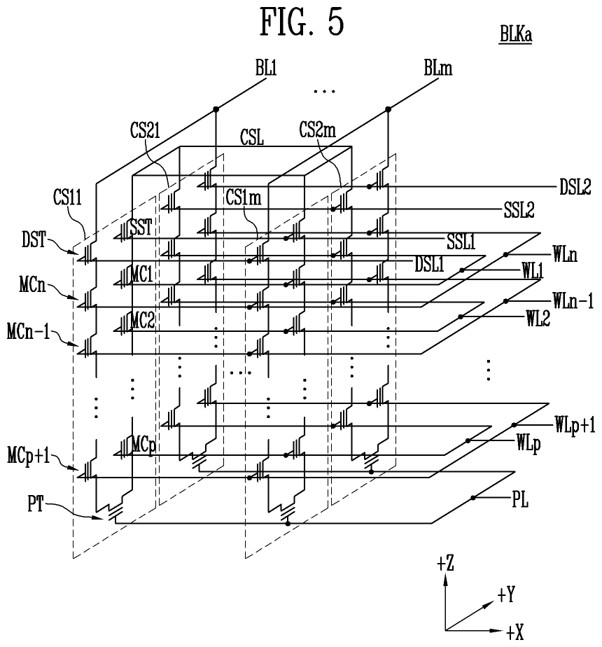

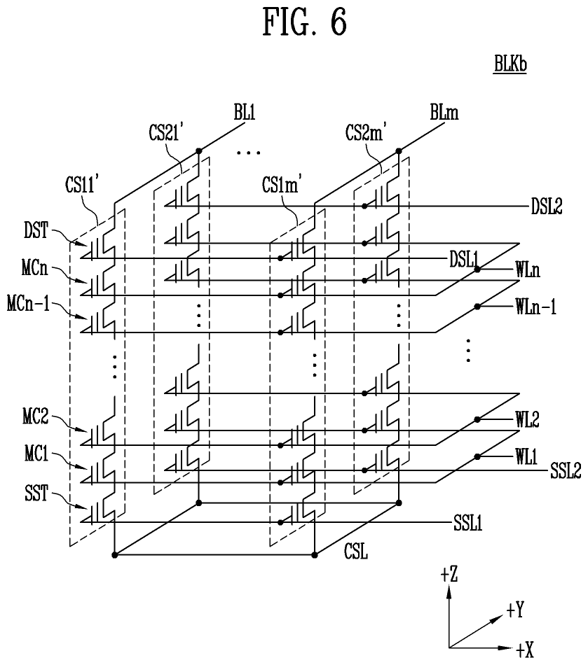

Referring to FIG. 4, the memory cell array 110 includes a plurality of memory blocks BLK1 to BLKz. Each memory block may have a three-dimensional (3D) structure. Each memory block includes a plurality of memory cells stacked on a substrate. Such memory cells are arranged in a positive X (+X) direction, a positive Y (+Y) direction, and a positive Z (+Z) direction. The structure of each memory block is described in detail below with reference to FIGS. 5 and 6.

FIG. 5 is a circuit diagram illustrating any one memory block BLKa of memory blocks BLK1 to BLKz of FIG. 4.

Referring to FIG. 5, the memory block BLKa includes a plurality of cell strings CS11 to CS1m and CS21 to CS2m. In an embodiment, each of the cell strings CS11 to CS1m and CS21 to CS2m may be formed in a ‘U’ shape. In the memory block BLKa, m cell strings are arranged in a row direction (i.e. a positive (+) X direction). In FIG. 5, two cell strings are illustrated as being arranged in a column direction (i.e. a positive (+) Y direction). However, this illustration is for clarity; it will be understood that three or more cell strings may be arranged in the column direction.

In an embodiment, a single memory block may include a plurality of sub-blocks. A single sub-block may include cell strings arranged in a ‘U’ shape in a single column.

Each of the plurality of cell strings CS11 to CS1m and CS21 to CS2m includes at least one source select transistor SST, first to n-th memory cells MC1 to MCn, a pipe transistor PT, and at least one drain select transistor DST.

The select transistors SST and DST and the memory cells MC1 to MCn may have similar structures. In an embodiment, each of the select transistors SST and DST and the memory cells MC1 to MCn may include a channel layer, a tunneling insulating layer, a charge storage layer, and a blocking insulating layer. In an embodiment, a pillar for providing the channel layer may be provided in each cell string. In an embodiment, a pillar for providing at least one of the channel layer, the tunneling insulating layer, the charge storage layer, and the blocking insulating layer may be provided in each cell string.

The source select transistor SST of each cell string is coupled between the common source line CSL and memory cells MC1 to MCp.

In an embodiment, the source select transistors of cell strings arranged in the same row are coupled to a source select line extending in a row direction, and source select transistors of cell strings arranged in different rows are coupled to different source select lines. In FIG. 5, source select transistors of cell strings CS11 to CS1m in a first row are coupled to a first source select line SSL1. The source select transistors of cell strings CS21 to CS2m in a second row are coupled to a second source select line SSL2.

In an embodiment, source select transistors of the cell strings CS11 to CS1m and CS21 to CS2m may be coupled in common to a single source select line.

The first to n-th memory cells MC1 to MCn in each cell string are coupled between the source select transistor SST and the drain select transistor DST.

The first to n-th memory cells MC1 to MCn may be divided into first to p-th memory cells MC1 to MCp and (p+1)-th to n-th memory cells MCp+1 to MCn. The first to p-th memory cells MC1 to MCp are sequentially arranged in a negative (−) Z direction and are coupled in series between the source select transistor SST and the pipe transistor PT. The (p+1)-th to n-th memory cells MCp+1 to MCn are sequentially arranged in the +Z direction and are coupled in series between the pipe transistor PT and the drain select transistor DST. The first to p-th memory cells MC1 to MCp and the (p+1)-th to n-th memory cells MCp+1 to MCn are coupled to each other through the pipe transistor PT. The gates of the first to n-th memory cells MC1 to MCn of each cell string are coupled to first to n-th word lines WL1 to WLn, respectively.

A gate of the pipe transistor PT of each cell string is coupled to a pipeline PL.

The drain select transistor DST of each cell string is coupled between the corresponding bit line and the memory cells MCp+1 to MCn. The cell strings in a row direction are coupled to drain select lines extending in a row direction. Drain select transistors of cell strings CS11 to CS1m in the first row are coupled to a first drain select line DSL1. Drain select transistors of cell strings CS21 to CS2m in a second row are coupled to a second drain select line DSL2.

Cell strings arranged in a column direction are coupled to bit lines extending in a column direction. In FIG. 5, cell strings CS11 and CS21 in a first column are coupled to a first bit line BL1. Cell strings CS1m and CS2m in an m-th column are coupled to an m-th bit line BLm.

Memory cells coupled to the same word line in cell strings arranged in the row direction form a single page. For example, memory cells coupled to the first word line WL1, among the cell strings CS11 to CS1m in the first row, form a single page. Memory cells coupled to the first word line WL1, among the cell strings CS21 to CS2m in the second row, form an additional page. Cell strings arranged in the direction of a single row may be selected by selecting any one of the drain select lines DSL1 and DSL2. A single page may be selected from the selected cell strings by selecting any one of the word lines WL1 to WLn.

In an embodiment, instead of the first to m-th bit lines BL1 to BLm, even bit lines and odd bit lines may be provided. Further, even-numbered cell strings, among the cell strings CS11 to CS1m or CS21 to CS2m arranged in the row direction, may be coupled to respective even bit lines. Odd-numbered cell strings, among the cell strings CS11 to CS1m or CS21 to CS2m arranged in the row direction, may be coupled to respective odd bit lines.

In an embodiment, one or more of the first to n-th memory cells MC1 to MCn may be used as dummy memory cells. For example, one or more dummy memory cells are provided to reduce an electric field between the source select transistor SST and the memory cells MC1 to MCp. Alternatively, the one or more dummy memory cells are provided to reduce an electric field between the drain select transistor DST and the memory cells MCp+1 to MCn. As more dummy memory cells are provided, the reliability of the operation of the memory block BLKa is improved, but the size of the memory block BLKa is increased. As fewer memory cells are provided, the size of the memory block BLKa is reduced, but the reliability of the operation of the memory block BLKa may be deteriorated.

In order to efficiently control the one or more dummy memory cells, each of the dummy memory cells may have a specific threshold voltage. Before or after the erase operation of the memory block BLKa is performed, a program operation may be performed on all or some of the dummy memory cells. When an erase operation is performed after the program operation has been performed, the threshold voltages of the dummy memory cells control the voltages that are applied to the dummy word lines coupled to respective dummy memory cells, and thus the dummy memory cells may have specific threshold voltages.

FIG. 6 is a circuit diagram illustrating an example of any one memory block BLKb of the memory blocks BLK1 to BLKz of FIG. 4.

Referring to FIG. 6, the memory block BLKb may include a plurality of cell strings CS11′ to CS1m′ and CS21′ to CS2m′. Each of the cell strings CS11′ to CS1m′ and CS21′ to CS2m′ extends in a positive (+) Z direction. Each of the cell strings CS11′ to CS1m′ and CS21′ to CS2m′ includes at least one source select transistor SST, first to n-th memory cells MC1 to MCn, and at least one drain select transistor DST, which are stacked on a substrate (not illustrated) below the memory block BLKb.

In an embodiment, a single memory block may include a plurality of sub-blocks. A single sub-block may include cell strings arranged in an ‘I’ shape in a single column.

The source select transistor SST of each cell string is coupled between a common source line CSL and memory cells MC1 to MCn. The source select transistors of cell strings arranged in the same row are coupled to the same source select line. Source select transistors of cell strings CS11′ to CS1m′ arranged in a first row are coupled to a first source select line SSL1. Source select transistors of cell strings CS21′ to CS2m′ arranged in a second row are coupled to a second source select line SSL2. In an embodiment, source select transistors of the cell strings CS11′ to CS1m′ and CS21′ to CS2m′ may be coupled in common to a single source select line.

The first to n-th memory cells MC1 to MCn in each cell string are coupled in series between the source select transistor SST and the drain select transistor DST. The gates of the first to n-th memory cells MC1 to MCn are coupled to first to n-th word lines WL1 to WLn, respectively.

The drain select transistor DST of each cell string is coupled between the corresponding bit line and the memory cells MC1 to MCn. Drain select transistors of cell strings arranged in a row direction are coupled to drain select lines extending in a row direction. The drain select transistors of the cell strings CS11′ to CS1m′ in the first row are coupled to a first drain select line DSL1. The drain select transistors of the cell strings CS21′ to CS2m′ in the second row are coupled to a second drain select line DSL2.

As a result, the memory block BLKb of FIG. 6 has an equivalent circuit similar to that of the memory block BLKa of FIG. 5 except that a pipe transistor PT is excluded from each cell string.

In an embodiment, instead of the first to m-th bit lines BL1 to BLm, even bit lines and odd bit lines may be provided. Further, even-numbered cell strings, among the cell strings CS11′ to CS1m′ or CS21′ to CS2m′ arranged in the row direction, may be coupled to respective even bit lines. Odd-numbered cell strings, among the cell strings CS11′ to CS1m′ or CS21′ to CS2m′ arranged in the row direction, may be coupled to respective odd bit lines.

In an embodiment, one or more of the first to n-th memory cells MC1 to MCn may be used as dummy memory cells. For example, the one or more dummy memory cells are provided to reduce an electric field between the source select transistor SST and the memory cells MC1 to MCn. Alternatively, the one or more dummy memory cells are provided to reduce an electric field between the drain select transistor DST and the memory cells MC1 to MCn. As the number of dummy memory cells that are provided increases, the reliability of operation of the memory block BLKb may be improved, whereas the size of the memory block BLKb may increase. As the number of dummy memory cells that are provided decreases, the size of the memory block BLKb may decrease, whereas the reliability of operation of the memory block BLKb may be deteriorated.

In order to efficiently control the one or more dummy memory cells, respective dummy memory cells may have specific threshold voltages. Before or after an erase operation on the memory block BLKb is performed, program operations may be performed on all or some of the dummy memory cells. When the erase operation is performed after the program operations have been performed, the dummy memory cells may have specific threshold voltages by controlling voltages to be applied to dummy word lines coupled to respective dummy memory cells.

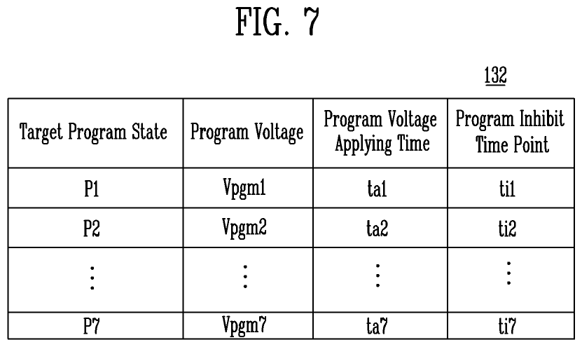

FIG. 7 is a diagram illustrating the configuration of the program setting table storage 132 of FIG. 2.

Referring to FIG. 7, the program setting table storage 132 may store program setting values for a ramp pulse program operation, which is described below with reference to FIG. 9.

The program setting values may include information about program voltage levels corresponding to target program states. The program setting values may include information about program voltage applying times corresponding to the target program states. The program setting values may include information about program inhibit time points corresponding to the target program states.

In FIG. 7, the program setting table storage 132 may store program setting values related to a triple-level cell which stores 3 bits. A target program state of the triple-level cell may be any one of first to seventh program states P1 to P7. The number of data bits stored in one memory cell is not limited to three.

For example, the program setting table storage 132 may store information about a program voltage Vpgm1, a program voltage applying time tat, and a program inhibit time point ti1 when the target program state is the first program state P1. The program setting table storage 132 may store information about a program voltage Vpgm2, a program voltage applying time tat, and a program inhibit time point tit when the target program state is the second program state P2. Similarly, the program setting table storage 132 may store information about a program voltage Vpgm7, a program voltage applying time ta7, and a program inhibit time point ti7 when the target program state is the seventh program state P7.

FIG. 8 is a diagram illustrating a coarse program operation (Coarse PGM) and a fine program operation (Fine PGM) according to an embodiment.

Referring to FIG. 8, the coarse program operation may include forming intermediate threshold voltage distributions of memory cells. The fine program operation may include forming final threshold voltage distributions of memory cells. Because the fine program operation is performed on the selected memory cells after the coarse program operation has been performed thereon, the coarse program operation may be a pre-program operation (Pre PGM), and the fine program operation may be a post-program operation (Post PGM). Both the pre-program operation and the post-program operation may be performed on selected memory cells based on the same data.

In FIG. 8, a description is made on the assumption that each memory cell is a triple-level cell which stores 3 bits. However, the number of data bits stored in the memory cell is not limited to three.

A triple-level cell may have an erased state E and any one of program states P1 to P7 as a target program state.

After the coarse program operation has been performed, the memory cells may have intermediate threshold voltage distributions corresponding to the program states P1 to P7. After the fine program operation has been performed, the memory cells may have final threshold voltage distributions corresponding to program states P1′ to P7′.

In an embodiment, the coarse program operation may be performed as a ramp pulse program operation, which is described below in FIG. 9. Therefore, since a program verify operation is skipped and only a number of program pulses corresponding to the target program state are applied, the program operation may be performed at high speed.

In an embodiment, the fine program operation may be performed as an incremental step pulse program operation, which is described below in FIG. 10. Because a program verify operation is performed in each program loop, the program operation may be performed with high accuracy.

In accordance with an embodiment of the present disclosure, the coarse program operation may form intermediate threshold voltage distributions of memory cells faster than the fine program operation. The fine program operation may form final threshold voltage distributions of memory cells with accuracy higher than that of the coarse program operation.

FIG. 9 is a diagram illustrating a ramp pulse program operation.

Referring to FIG. 9, a program voltage may be applied to a selected word line coupled to memory cells selected from among a plurality of memory cells. A program pass voltage may be applied to unselected word lines coupled to unselected memory cells among the plurality of memory cells. Before the program voltage is applied, a program enable voltage may be applied to bit lines coupled to the selected memory cells. The program enable voltage may be a ground voltage.

The ramp pulse program operation may be performed based on program setting values stored in the program setting table storage 132, described above with reference to FIG. 7.

In FIG. 9, each memory cell may be a triple-level cell, which is capable of storing three bits of data. However, the number of data bits stored in the memory cell is not limited to three.

A first program voltage Vpgm1 corresponding to a first program state may be applied to the selected word line coupled to the selected memory cells during a first program voltage applying time ta1. At a first program inhibit time point ti1, a program inhibit voltage may be applied to bit lines coupled to memory cells to be programmed to the first program state, among the selected memory cells. The program inhibit voltage may be a supply voltage.

A second program voltage Vpgm2 corresponding to a second program state may be applied to the selected word line coupled to the selected memory cells during a second program voltage applying time ta2. At a second program inhibit time point tit, a program inhibit voltage may be applied to bit lines coupled to memory cells to be programmed to the second program state, among the selected memory cells.

Similarly, a seventh program voltage Vpgm7 corresponding to a seventh program state may be applied to the selected word line coupled to the selected memory cells during a seventh program voltage applying time ta7. At a seventh program inhibit time point ti7, a program inhibit voltage may be applied to bit lines coupled to memory cells to be programmed to the seventh program state, among the selected memory cells.

In an embodiment, the program inhibit time point may be either a time point at which the program voltage applied to the selected word line is changed, or a time point previous thereto as shown in FIG. 9. For example, the first program inhibit time point ti1 may be a time point at which application of the first program voltage is stopped, i.e., at the termination of the first program voltage applying time ta1. Alternatively, the first program inhibit time point ti1 may be a time point before the first program voltage applying time ta1 ends as shown in FIG. 9. In the ramp pulse program operation, a program verify operation is skipped, and thus the program inhibit time point may be determined based on previous test results at a manufacturing step not based on the program verify operation results.

Each step voltage may be the voltage difference between program voltages respectively corresponding to adjacent target program states. For example, a first step voltage ΔS1 may be the voltage difference between the first program voltage Vpgm1 and the second program voltage Vpgm2. A second step voltage ΔS2 may be the voltage difference between the second program voltage Vpgm2 and a third program voltage Vpgm3. In this way, in the case of the triple-level cell, the first to sixth step voltages ΔS1 to ΔS6 may be determined.

In an embodiment, the amount (i.e., increment) by which the program voltage is increased as the target program state becomes higher may be constant. In other words, the magnitudes of respective step voltages may be equal to each other. In other embodiments, the amount (increment) by which the program voltage is increased as the target program state becomes higher may be determined depending on the target program state. In that case, the magnitudes of respective step voltages may be different from each other. In other embodiments, the magnitude of at least one of all step voltages may be different from those of the remaining step voltages.

In the ramp pulse program operation, a program verify operation is skipped, and thus the program voltage increased step by step may be successively applied to the selected word line. Therefore, in comparison with the incremental step pulse program operation, which is described below in FIG. 10, a bit line precharge operation and a bit line discharge operation of a program verify operation are not performed in the ramp pulse program operation, and thus the time it takes to perform the program operation may be shortened.

FIG. 10 is a diagram illustrating an incremental step pulse program (ISPP) operation.

In FIG. 10, by way of example, each memory cell is assumed to be a multi-level cell (MLC) which stores 2-bit data. However, the scope of the present disclosure is not limited thereto, and each memory cell may be a triple-level cell (TLC) which stores 3-bit data or a quad-level cell (QLC) which stores 4-bit data. The number of data bits stored in each memory cell may be one or more.

The memory device may perform a program operation so that each of selected memory cells has a threshold voltage corresponding to any one of a plurality of program states P1, P2, and P3 by performing a plurality of program loops PL1 to PLn.

Each of the program loops PL1 to PLn may include a program voltage apply step (PGM step) of applying a program voltage to a selected word line coupled to the selected memory cells and a verify step of determining whether the memory cells have been programmed by applying verify voltages.

For example, in the first program loop PL1, a first program voltage Vpgm1 is applied, and thereafter first to third verify voltages V_vfy1 to V_vfy3 are sequentially applied so as to verify the program states of the selected memory cells. Here, the memory cells, of which the target program state is the first program state P1, may be verified using the first verify voltage V_vfy1. Memory cells, of which the target program state is the second program state P2, may be verified using the second verify voltage V_vfy2. Memory cells, of which the target program state is the third program state P3, may be verified using the third verify voltage V_vfy3.

The memory cells which have passed verification (i.e., verify-passed) through respective verify voltages V_vfy1 to V_vfy3 may be determined to have the target program states, and may then be program-inhibited in the second program loop PL2. In other words, a program inhibit voltage may be applied to a bit line coupled to the memory cell having passed the verification from the second program loop PL2.

In order to program memory cells other than the program-inhibited memory cells in the second program loop PL2, a second program voltage Vpgm2 higher than the first program voltage Vpgm1 by a unit voltage ΔVpgm is applied to a selected word line. Thereafter, a verify operation is performed in the same way as the verify operation in the first program loop PL1. In an example, the term “verify pass” indicates that a memory cell is read as an off-cell through the corresponding verify voltage.

As described above, when the memory device programs multi-level cells (MLC) which store 2 bits, the memory device individually verifies the memory cells having respective program states as target program states using the first to third verify voltages V_vfy1 to V_vfy3.

During the verify operation, the corresponding verify voltage may be applied to the selected word line, which is a word line coupled to selected memory cells, and the page buffer of FIG. 2 may determine whether the selected memory cells have passed verification based on currents that flow through bit lines respectively coupled to the selected memory cells or voltages that are applied to the bit lines.

In the incremental step pulse program operation, a program verify operation is performed in each program loop, and thus the threshold voltage distributions of memory cells may be formed with higher accuracy. A time point at which a program inhibit voltage is to be applied to the bit lines coupled to memory cells may be determined based on the result of the program verify operation.

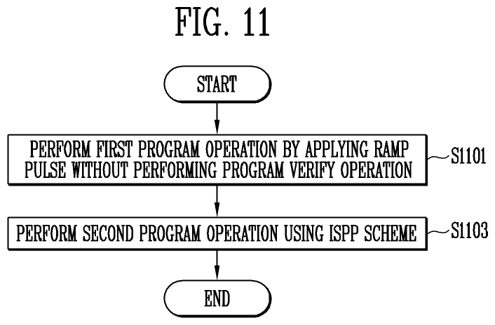

FIG. 11 is a flowchart illustrating the operation of a memory device according to an embodiment.

Referring to FIG. 11, at operation S1101, the memory device may perform a first program operation by applying a ramp pulse without performing a program verify operation. The first program operation may be a coarse program operation of forming intermediate threshold voltage distributions of selected memory cells. During the first program operation, a program voltage increased step by step may be successively applied to a selected word line coupled to the selected memory cells.

At operation S1103, the memory device may perform a second program operation using an incremental step pulse program (ISPP) scheme. The second program operation may be a fine program operation of forming final threshold voltage distributions of the selected memory cells. During the second program operation including a plurality of program loops, a program pulse apply operation and a program verify operation may be performed in each program loop.

In accordance with embodiments of the present disclosure, a memory device having improved program operation performance and a method of operating the memory device are provided.

While the present invention has been illustrated and described in the context of various embodiments, those skilled in the art will recognize in view of the present disclosure that variations and modifications may be made to any of the disclosed embodiments within the spirit and scope of the present invention. The present invention encompasses all such variations and modifications that fall within the scope of the claims.

What is claimed is:

1. A memory device, comprising:
a plurality of memory cells;
a peripheral circuit configured to perform a first program operation and a second program operation on selected memory cells among the plurality of memory cells; and
control logic configured to control the peripheral circuit to apply stepwise increasing and successive program pulses on the selected memory cells in a first program operation, and to apply program pulses and verify pulses on the selected memory cells in the second program operation.

2. The memory device according to claim 1, wherein the control logic controls the peripheral circuit to perform the first program operation as a ramp pulse program operation.

3. The memory device according to claim 2, wherein the control logic controls the peripheral circuit to perform the second program operation as an incremental step pulse program operation.

4. The memory device according to claim 1, wherein the first program operation is a coarse program operation of forming an intermediate threshold voltage distribution of the selected memory cells.

5. The memory device according to claim 4, wherein the second program operation is a fine program operation of forming a final threshold voltage distribution of the selected memory cells.

6. The memory device according to claim 1, wherein the control logic comprises:
a program operation controller configured to control the peripheral circuit to perform the first program operation and the second program operation on the selected memory cells; and
a program setting table storage configured to store program setting values related to the first program operation and the second program operation.

7. The memory device according to claim 6, wherein the program setting values related to the first program operation include information on a program voltage level, a program voltage application time, and a program inhibit time point that respectively correspond to a target program state of the selected memory cells in the first program operation.

8. The memory device according to claim 7, wherein:
the program operation controller controls the peripheral circuit to apply, in the first program operation, a program voltage corresponding to the target program state on the selected memory cells during the program voltage applying time corresponding to the target program state, based on the program setting values, and
the program voltage is successive and stepwise increasing as the target program state becomes higher.

9. The memory device according to claim 8, wherein the program voltage is increased by a constant increment.

10. The memory device according to claim 8, wherein the program voltage is increased by an increment determined based on the target program state.

11. The memory device according to claim 8, wherein the program operation controller controls the peripheral circuit to apply a program inhibit voltage to bit lines coupled to the selected memory cells at the program inhibit time point corresponding to the target program state based on the program setting values.

12. The memory device according to claim 8, wherein:
the program operation controller controls the peripheral circuit to apply a program pass voltage on unselected memory cells among the plurality of memory cells, and
the program pass voltage is successive and stepwise increasing as the target program state becomes higher.

13. A method of operating a memory device, comprising:
performing a first program operation of applying successive and stepwise increasing program pulses on selected memory cells among a plurality of memory cells; and
performing a second program operation on the selected memory cells, the second program operation including a program verify operation and a program pulse apply operation.

14. The method according to claim 13, wherein:
the first program operation is performed as a ramp pulse program operation, and
the second program operation is performed as an incremental step pulse program operation.

15. The method according to claim 13, wherein:
the first program operation is a coarse program operation of forming an intermediate threshold voltage distribution of the selected memory cells, and
the second program operation is a fine program operation of forming a final threshold voltage distribution of the selected memory cells.

16. The method according to claim 13, wherein performing the first program operation comprises:
applying a program voltage corresponding to a target program state to the selected memory cells during a program voltage applying time corresponding to the target program state, based on program setting values related to the first program operation, and
the program voltage is successive and stepwise increasing as the target program state becomes higher.

17. The method according to claim 16, wherein the program voltage is increased by an increment determined based on the target program state.

18. The method according to claim 16, wherein the program setting values related to the first program operation include information on a program voltage level, the program voltage application time, and a program inhibit time point that respectively correspond to the target program state of the selected memory cells in the first program operation.

19. The method according to claim 18, wherein performing the first program operation further comprises:
applying a program inhibit voltage to bit lines coupled to the selected memory cells at the program inhibit time point corresponding to the target program state.

20. The method according to claim 18, wherein performing the first program operation further comprises:
applying a program pass voltage to unselected memory cells among the plurality of memory cells,
wherein the program pass voltage is successive and stepwise increasing as the target program state becomes higher.

21. A memory device comprising:
a plurality of memory cells;
a peripheral circuit configured to apply one or more voltages to a word line coupled to selected memory cells among the plurality of memory cells, the one or more voltages associated with one or more program operations on the selected memory cells; and
control logic configured to control the peripheral circuit to perform a coarse program operation and a fine program operation on the selected memory cells, the coarse program operation including a program operation of applying ramp pulses and excluding a program verify operation and the fine program operation including a program operation and a program verify operation.
